(19) United States
(12) Patent Application Publication
(10) Pub. No.: US 2025/0386615 A1
(43) Pub. Date: Dec. 18, 2025

(54) LIGHT DETECTION APPARATUS AND ITS MANUFACTURING METHOD

(71) Applicant: SONY SEMICONDUCTOR SOLUTIONS CORPORATION, KANAGAWA (JP)

(72) Inventor: TATSUYA NAKATA, KANAGAWA (JP)

(21) Appl. No.: 18/878,754

(22) PCT Filed: Jul. 1, 2022
(86) PCT No.: PCT/JP2022/026527

§ 371 Date: Dec. 24, 2024

(51) Int. Cl. H10F 39/00; H10F 30/225

(52) U.S. Cl. CPC H10F 39/811; H10F 30/225; H10F 39/011; H10F 39/807

(57) ABSTRACT

A light detection apparatus according to an embodiment of the present disclosure includes a semiconductor substrate, a light receiver, a trench, a multiplier that is a first electrically-conductive type, and a contactor. The semiconductor substrate has a first surface and a second surface facing each other, and has a pixel array in which a plurality of pixels is disposed into an array shape in an in-plane direction. The light receiver is provided inside the semiconductor substrate for each of the pixels, and generates, through photoelectric conversion, carriers in accordance with an amount of light received. The trench is provided, for each of the pixels, to the first surface of the semiconductor substrate. The multiplier that is the first electrically-conductive type is provided to a bottom surface of the trench, and allows the carriers generated in the light receiver to undergo avalanche multiplication. The contactor includes an electrically-conductive material buried in the trench, and is in contact with the multiplier.

### TECHNICAL FIELD

The present disclosure relates to a light detection apparatus that uses an avalanche photodiode, for example, and its manufacturing method.

### BACKGROUND ART

A light detection apparatus including an avalanche photodiode (APD) has been developed (for example, see PTL 1).

### CITATION LIST

### Patent Literature

PTL 1: Japanese Unexamined Patent Application Publication No. 2021-27084

### SUMMARY OF THE INVENTION

In an APD, generally, a high voltage of approximately 20 V is applied between an anode and a cathode to form a region of a high electric field. Therefore, a leak current may flow when a distance in a horizontal direction between the anode and the cathode is shortened due to a finer configuration. It is possible to confirm this phenomenon from a result of measurement, which takes a form of a deteriorated dark count rate (DCR), which corresponds to a dark current. The phenomenon is called edge breakdown (EBD). Therefore, it is desirable to provide a light detection apparatus that makes it possible to make a finer configuration and a suppressed DCR compatible to each other, and its manufacturing method.

A light detection apparatus according to an embodiment of the present disclosure includes a semiconductor substrate, a light receiver, a trench, a multiplier that is a first electrically-conductive type, and a contactor. The semiconductor substrate has a first surface and a second surface facing each other, and has a pixel array in which a plurality of pixels is disposed into an array shape in an in-plane direction. The light receiver is provided inside the semiconductor substrate for each of the pixels, and generates, through photoelectric conversion, carriers in accordance with an amount of light received. The trench is provided, for each of the pixels, to the first surface of the semiconductor substrate. The multiplier that is the first electrically-conductive type is provided to a bottom surface of the trench, and allows the carriers generated in the light receiver to undergo avalanche multiplication. The contactor includes an electrically-conductive material buried in the trench, and is in contact with the multiplier.

A manufacturing method for the light detection apparatus according to the embodiment of the present disclosure includes six steps described below:
(A) forming, inside a semiconductor substrate having a first surface and a second surface, for each of pixels, a light receiver generating, through photoelectric conversion, carriers in accordance with an amount of light received;
(B) forming, on the first surface of the semiconductor substrate, an oxide film having a first opening for each of the pixels;
(C) using the oxide film as a mask and performing dry etching to form a trench immediately below the opening on the semiconductor substrate;
(D) using the oxide film as a mask and performing ion implantation to form a multiplier that is a first electrically-conductive type immediately below the trench in the semiconductor substrate, the multiplier allowing the carriers generated in the light receiver to undergo avalanche multiplication; and
(E) burying an electrically-conductive material in the trench to form a contactor that is in contact with the multiplier.

### BRIEF DESCRIPTION OF DRAWING

FIG. 1 is a diagram illustrating a configuration example of a cross section of lamination layers in a light detection apparatus according to an embodiment of the present disclosure.

FIG. 2 is a diagram illustrating an example of an outline configuration of the light detection apparatus illustrated in FIG. 1.

FIG. 3 is a diagram illustrating an example of a circuit configuration of a pixel illustrated in FIG. 2.

FIG. 4 is an enlarged diagram of a multiplier and its peripheral portion illustrated in FIG. 1.

FIG. 5 is a diagram illustrating an example of a plan configuration of the pixel illustrated in FIG. 2.

FIG. 6 is a diagram illustrating another example of the plan configuration of the pixel illustrated in FIG. 2.

FIG. 7 is a diagram illustrating an example of a manufacturing method for the light detection apparatus illustrated in FIG. 1.

FIG. 8 is a diagram illustrating a step subsequent to that illustrated in FIG. 7.

FIG. 9 is a diagram illustrating a step subsequent to that illustrated in FIG. 8.

FIG. 10 is a diagram illustrating a step subsequent to that illustrated in FIG. 9.

FIG. 11 is a diagram illustrating a step subsequent to that illustrated in FIG. 10.

FIG. 12 is a diagram illustrating a step subsequent to that illustrated in FIG. 11.

FIG. 13 is a diagram illustrating a step subsequent to that illustrated in FIG. 12.

FIG. 14 is a diagram illustrating a step subsequent to that illustrated in FIG. 13.

FIG. 15 is a diagram illustrating a step subsequent to that illustrated in FIG. 14.

FIG. 16 is a diagram illustrating a step subsequent to that illustrated in FIG. 15.

FIG. 17 is a diagram illustrating a step subsequent to that illustrated in FIG. 16.

FIG. 18 is a diagram illustrating a step subsequent to that illustrated in FIG. 17.

FIG. 19 is a diagram illustrating a modification example of the configuration of the cross section of the lamination layers in the light detection apparatus illustrated in FIG. 1.

FIG. 20 is a diagram illustrating an example of the plan configuration of the pixel in the light detection apparatus illustrated in FIG. 19.

FIG. 21 is a diagram illustrating a modification example of the manufacturing method for the light detection apparatus illustrated in FIG. 1.

FIG. 22 is a diagram illustrating a step subsequent to that illustrated in FIG. 21.

FIG. 23 is a diagram illustrating a step subsequent to that illustrated in FIG. 22.

FIG. 24 is a diagram illustrating a step subsequent to that illustrated in FIG. 23.

FIG. 25 is a diagram illustrating a step subsequent to that illustrated in FIG. 24.

FIG. 26 is a diagram illustrating a modification example of the plan configuration of the pixel in the light detection apparatus as illustrated in FIG. 1 and other drawings.

FIG. 27 is a diagram illustrating another modification example of the configuration of the cross section of the lamination layers in the light detection apparatus as illustrated in FIG. 1 and other drawings.

FIG. 28 is a diagram illustrating still another modification example of the configuration of the cross section of the lamination layers in the light detection apparatus as illustrated in FIG. 1 and other drawings.

FIG. 29 is a diagram illustrating still another modification example of the configuration of the cross section of the lamination layers in the light detection apparatus as illustrated in FIG. 1 and other drawings.

FIG. 30 is a functional block diagram illustrating an example of an electronic apparatus using the light detection apparatus as illustrated in FIG. 1 and other drawings.

FIG. 31 is a block diagram depicting an example of schematic configuration of a vehicle control system.

FIG. 32 is a diagram of assistance in explaining an example of installation positions of an outside-vehicle information detecting section and an imaging section.

### MODES FOR CARRYING OUT THE INVENTION

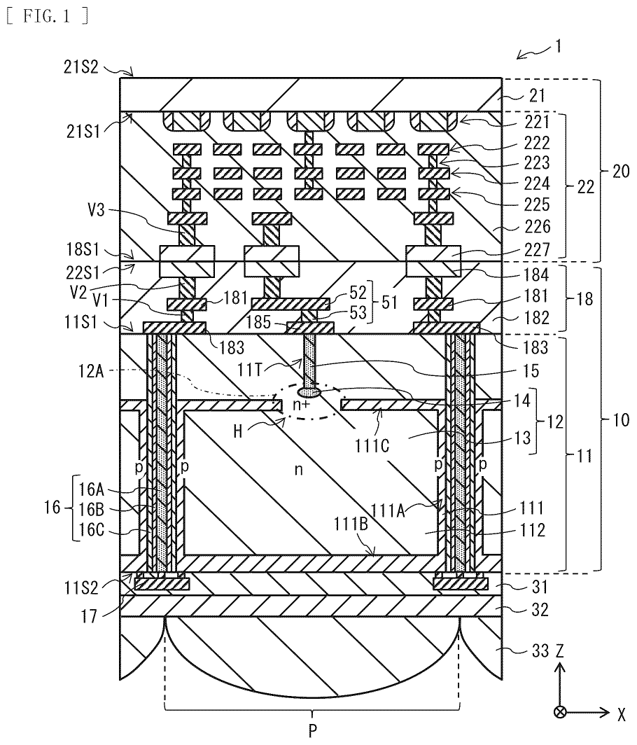

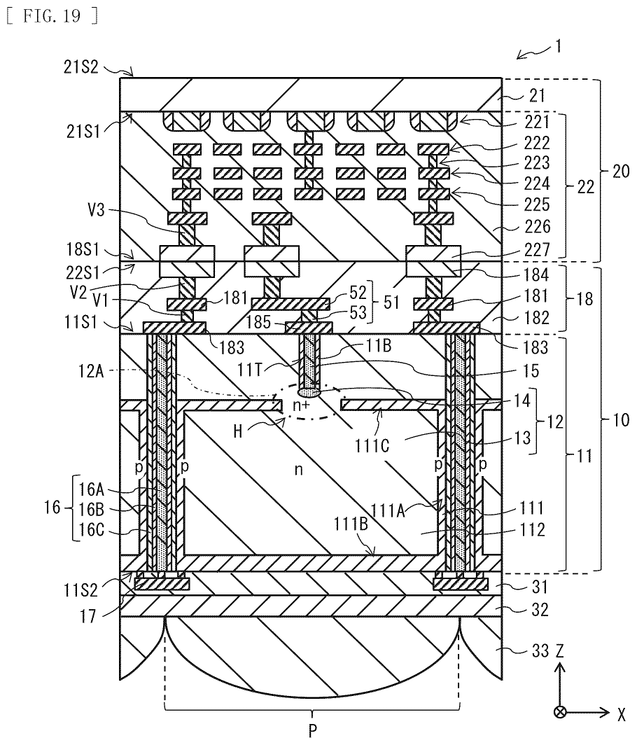

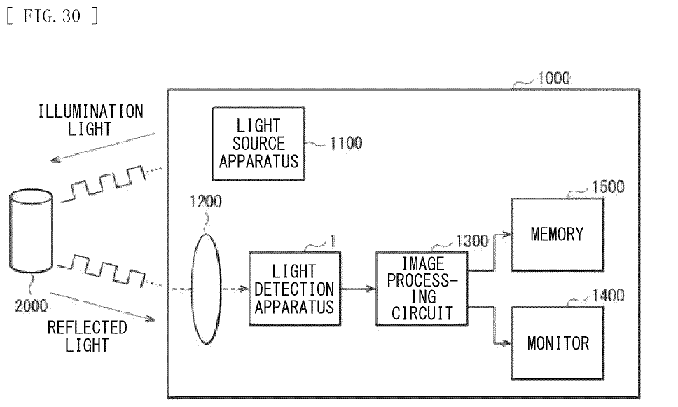

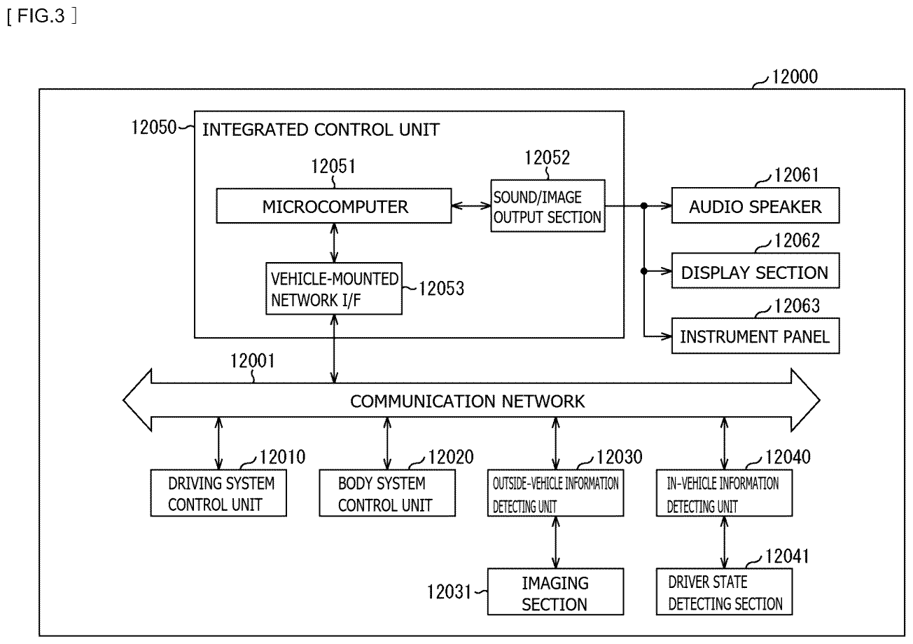

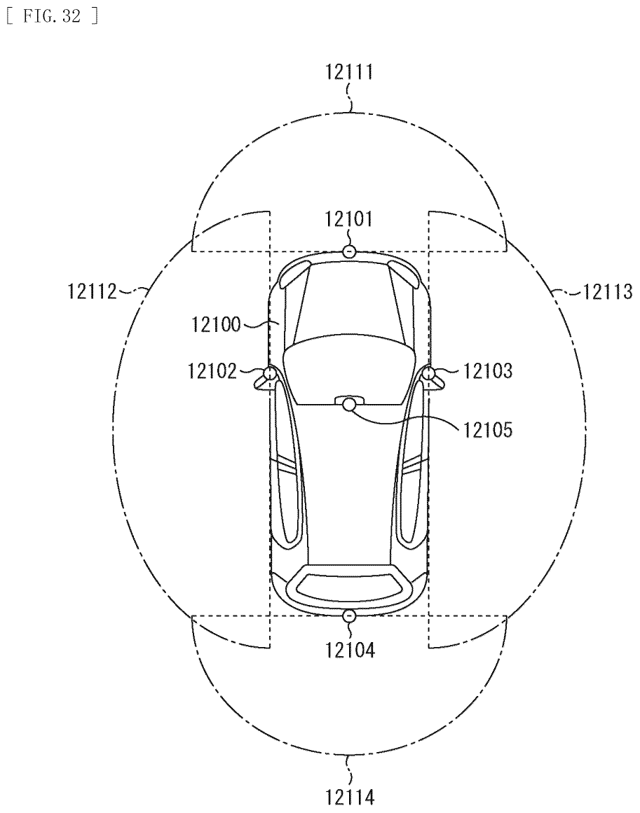

In the following, an embodiment of the present disclosure will be described in detail with reference to the drawings. It is to be noted that the embodiment described below is a specific example of the present disclosure, and the present disclosure is not limited to the following embodiment. In addition, the arrangement, dimensions, dimension ratios, and the like of components in the present disclosure are not limited to the embodiment illustrated in each drawing. It is to be noted that the description will be given in the following order.
1. Background
2. Embodiment (FIGS. 1 to 18)
3. Modification Examples (FIGS. 19 to 29)
4. Application Example (FIG. 30)
5. Practical Example (FIGS. 31 and 32)

### 1. Background

An avalanche photodiode (APD) has a multiplication mechanism based on a region of a high electric field, and represents one technique that makes it possible to detect electrons. In an APD, generally, a high voltage of approximately 20 V is applied between an anode and a cathode to form a region of a high electric field. Therefore, a leak current may flow when a distance in the horizontal direction between the anode and the cathode is shortened due to a finer configuration. It is possible to confirm this phenomenon from a result of measurement, which takes a form of a deteriorated dark count rate (DCR), which corresponds to a dark current. The phenomenon is called edge breakdown (EBD).

Therefore, one idea for extending a distance between an anode and a cathode is to dispose the anode at a corner of a pixel, for example. Thereby, a depletion layer is expanded, making it possible to mitigate generation of an electric field in the horizontal direction. At this time, electrons generated at an interface (an Si interface) of a pixel separation structure do not enter a region of a high electric field, but are collected at the cathode, making it possible to suppress a DCR.

However, along with further increased demands of a finer configuration in recent years, a width of a depletion layer as described above has been narrowed, resulting in an expanded region of a high electric field to an interface of a pixel separation structure. As a result, such an issue has arisen that electrons generated at the interface of the pixel separation structure pass through the region of the high electric field, which are to be counted as a DCR. Therefore, to address the issue described above, the inventors of the present application have retrieved one idea of adjusting a position and a size of a cathode to prevent a region of a high electric field from expanding to an interface of a pixel separation structure. Its specific configuration and its manufacturing method will now be described herein.

### 2. Embodiment

### Configuration

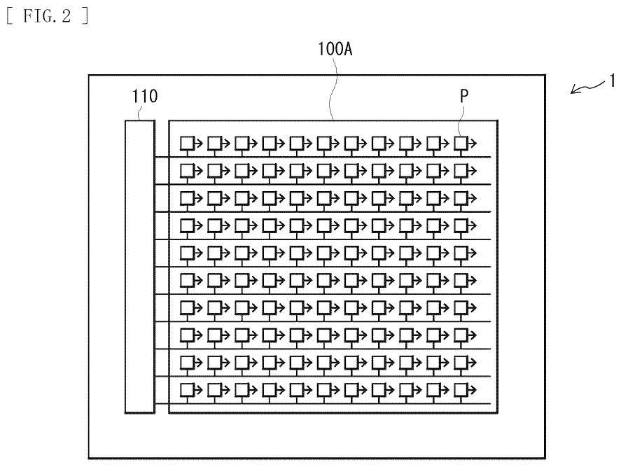

FIG. 1 schematically illustrates an example of a cross-sectional configuration of a light detection apparatus 1 according to an embodiment of the present disclosure. FIG. 2 illustrates an outline configuration of the light detection apparatus 1 illustrated in FIG. 1. The light detection apparatus 1 is applicable to, for example, a distance image sensor that uses a Time-of-Flight (ToF) method to measure a distance (a distance image apparatus 1000 described later, see FIG. 30) and an image sensor.

The light detection apparatus 1 includes, for example, a pixel array 100A in which a plurality of pixels P is disposed into an array shape in a row direction and a column direction. The light detection apparatus 1 includes, as illustrated in FIG. 2, a bias voltage applicator 110 in addition to the pixel array 100A. The bias voltage applicator 110 is an electric circuit that applies a bias voltage for each of the pixels P in the pixel array 100A. In the present embodiment, a case when electrons are read as a signal electric charge will be described.

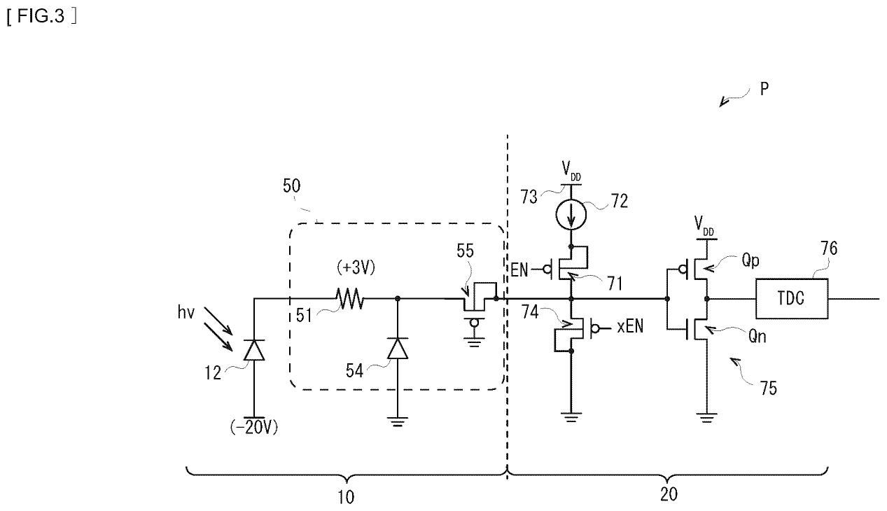

FIG. 3 is a circuit diagram illustrating an example of an equivalent circuit to each of the unit pixels P in the light detection apparatus 1 illustrated in FIG. 1. The light detection apparatus 1 is applicable to, for example, a distance image sensor that uses a Time-of-Flight (ToF) method to measure a distance (the distance image apparatus 1000 described later, see FIG. 30) and an image sensor.

### Circuit Configuration of Light Detection Apparatus 1

As illustrated in FIG. 3, each of the pixels P includes a light receiving element 12, a clamp circuit 50 serving as a protection circuit, a first control transistor 71, an electric current source 72, a terminal 73, a second control transistor 74, and a reading circuit 75.

The light receiving element 12 performs photoelectric conversion to convert light that has entered into an electric signal, and outputs the converted electric signal. The light receiving element 12 performs photoelectric conversion to convert light that has entered (photons) into an electric signal, and outputs a pulse in accordance with the photons that have entered. The light receiving element 12 is, for example, a single photon avalanche photo diode (an SPAD element). An SPAD element has a characteristic of, for example, forming an avalanche multiplication region (depletion layer) 12A when a large negative voltage is applied to a cathode, allowing electrons generated in accordance with entry of one photon to undergo avalanche multiplication to allow a large electric current to flow. An anode of the light receiving element 12 is coupled to, for example, the bias voltage applicator 110. A cathode of the light receiving element 12 is coupled to, for example, the terminal 73, to which an electric power source voltage V_{DD} is applied, via the first control transistor 71 and the electric current source 72. The electric power source voltage V_{DD} is, for example, a voltage of approximately 3 V. The cathode of the light receiving element 12 is coupled to a source terminal of the first control transistor 71. A device voltage V_{B} is applied from a device voltage applicator to the anode of the light receiving element 12. The device voltage V_{B} is a large negative voltage causing avalanche multiplication to occur, that is, a voltage equal to or higher than a break-down voltage (for example, approximately −20 V).

The first control transistor 71 includes a p-type metal-oxide-semiconductor field-effect transistor (MOSFET), and is also called a quenching resistance element. The first control transistor 71 is coupled in series to the light receiving element 12 via the clamp circuit 50. The source terminal of the first control transistor 71 is coupled to the cathode of the light receiving element 12. A drain terminal of the first control transistor 71 is coupled to the terminal 73 via the electric current source 72. When an enable signal EN applied to a gate electrode becomes a low level, the first control transistor 71 becomes an electrically-conductive state, allowing an electric current supplied from the electric current source 72 to flow into the light receiving element 12. The second control transistor 74 is coupled between the cathode of the light receiving element 12 and a reference electric potential node (for example, ground). The second control transistor 74 includes, for example, an N-type MOS transistor. When a signal xEN that is opposite in phase to the enable signal EN is applied to a gate electrode, the second control transistor 74 becomes an electrically-conductive state, allowing a voltage applied to the light receiving element 12 to be equal to or lower than the break-down voltage to allow the light receiving element 12 to be in a deactivated state.

The reading circuit 75 is, for example, a complementary MOS (CMOS) inverter circuit including a P-type MOS transistor Qp and an N-type MOS transistor Qn. The reading circuit 75 includes an input terminal coupled to the cathode of the light receiving element 12, the source terminal of the first control transistor 71, and the second control transistor 74 and an output terminal coupled to an arithmetic processor 76 described later. The reading circuit 75 outputs a light receiving signal based on carriers (a signal electric charge) multiplied in the light receiving element 12. More specifically, the reading circuit 75 shapes a voltage generated based on electrons multiplied in the light receiving element 12. The reading circuit 75 outputs, to the arithmetic processor 76, for example, a light receiving signal based on which a pulse waveform is to be generated, at a point in time of arrival of one photon, which serves as a start point. For example, the arithmetic processor 76 performs arithmetic processing of acquiring a distance to a target of imaging based on a timing when a pulse indicating a point in time of arrival of one photon is generated in each light receiving signal to acquire the distance for each of the unit pixels P. Based on the distances, a distance image in which the distances to the target of imaging that is detected by the plurality of unit pixels P are arranged on a plane is generated.

The clamp circuit 50 is a protection circuit provided between the light receiving element 12 and an input end of the reading circuit 75. The clamp circuit 50 is, for example, an excessive-voltage protection circuit that protects the P-type MOS transistor Qp and the N-type MOS transistor Qn, which form the reading circuit 75, and the first control transistor 71 and the second control transistor 74 from an excessive voltage that is generated when the light receiving element 12 receives laser light at a large amount.

As described above, providing the clamp circuit 50 between the light receiving element 12 and the input end of the reading circuit 75 makes it possible to protect the reading circuit 75 and other components from an excessive voltage even when the light receiving element 12 receives laser light at a large amount equal to or greater than a predetermined amount of light (equal to or greater than an expected amount of light).

The clamp circuit 50 includes, specifically, as illustrated in FIG. 3, for example, a resistance element 51, a first clamp element 54, and a second clamp element 55. The resistance element 51 has one end coupled to a cathode electrode of the light receiving element 12. The first clamp element 54 includes, for example, a clamp diode having a cathode coupled to another end (an output end) of the resistance element 51 and an anode coupled to the reference electric potential node (for example, the ground).

The resistance element 51 is provided to restrict and prevent, in value, an electric current flowing into the first clamp element 54 from exceeding a rated forward electric current when an excessive voltage has been generated in the light receiving element 12. The clamp diode serving as the first clamp element 54 clamps, when an excessive voltage exceeding a clamp voltage is generated in the light receiving element 12, the excessive voltage to a constant voltage (a forward direction voltage V_{f}).

Note that the first clamp element 54 is not limited to a clamp diode. It is possible to use, for example, a schottky barrier diode as the first clamp element 54, instead of a clamp diode.

The second clamp element 55 includes, for example, a P-type MOS transistor. The second clamp element 55 is coupled between the first clamp element 54 (for example, the anode of the clamp diode) and a node N to which the input end of the reading circuit 75 is coupled. The P-type MOS transistor serving as the second clamp element 55 has a gate electrode coupled to the reference electric potential node (for example, the ground) and a back gate coupled to a source electrode.

Note herein that, as an example, clamp operation when an excessive voltage of minus several tens of V has been generated in the light receiving element 12 will now be described. As described above, the clamp diode serving as the first clamp element 54 clamps an excessive voltage generated in the light receiving element 12 to a constant voltage (the forward direction voltage V_{f}). With this clamp operation, the excessive voltage generated in the light receiving element 12 is clamped to a negative voltage ranging from approximately −1 V to approximately −3 V, for example.

Note herein that, when a negative voltage is generated through clamp operation in the first clamp element 54, the negative voltage may exceed a voltage at which the MOS transistor is able to withstand, which will be described later. To address this issue of a negative voltage, the second clamp element 55 is provided. That is, the second clamp element 55 clamps a voltage at the node N to which the input end of the reading circuit 75 is coupled to a voltage V_{gs} (for example, approximately 0.5 V) between the gate and the source of the P-type MOS transistor. Thereby, performing clamp operation in the first clamp element 54 makes it possible to solve the issue of a negative voltage.

### Structure of Light Detection Apparatus 1

The light detection apparatus 1 is a so-called back surface illumination type light detection apparatus. As illustrated in FIG. 1, the light detection apparatus 1 includes, for example, a sensor substrate 10 and a logic substrate 20 laminated on a front surface of the sensor substrate 10, and receives light from a back surface of the sensor substrate 10. Note herein that, the front surface of the sensor substrate 10 represents, for example, a first surface 11S1 that is also a front surface of the semiconductor substrate 11 forming the sensor substrate 10. The back surface of the sensor substrate 10 represents, for example, a second surface 11S2 that is also a back surface of the semiconductor substrate 11 forming the sensor substrate 10.

The light detection apparatus 1 includes, as illustrated in FIG. 1, the light receiving element 12 for each of the pixels P. The light receiving element 12 includes a light receiver 13 and a multiplier 14. The light receiver 13 and the multiplier 14 are formed and buried inside the semiconductor substrate 11.

Note that the letter “p” illustrated in FIG. 1 represents a p-type semiconductor region. The letter “n” illustrated in FIG. 1 represents an n-type semiconductor region. The symbol “+” at an end of the letter “p” represents concentration of an impurity in the p-type semiconductor region. In a location added with the symbol “+”, it is indicated that the concentration of an impurity is high, compared with a location added with no “+”. The same applies to the later drawings.

The sensor substrate 10 includes, for example, the semiconductor substrate 11, which includes a silicon substrate, and a lamination wiring layer 18. The semiconductor substrate 11 has the first surface 11S1 and the second surface 11S2 facing each other.

The semiconductor substrate 11 includes a p-well 111 that is common to the plurality of pixels P. The p-well 111 represents, for example, a p-type semiconductor region in which the concentration of an impurity is controlled to that of a p-type. The semiconductor substrate 11 is provided with, for each of the pixels P, an n-type semiconductor region 112 in which the concentration of an impurity is controlled to that of an n-type, for example, thereby forming the light receiver 13 for each of the pixels P. Each of the n-type semiconductor regions 112 has a side surface surrounded by the p-well 111. The p-well 111 is provided, for example, to the second surface 11S2 of the semiconductor substrate 11 and a place at a predetermined depth from the first surface 11S1 in the semiconductor substrate 11. Therefore, the p-well 111 includes, for example, a region 111A provided to cover a side surface of the light receiver 13, a region 111B provided to the second surface 11S2 of the semiconductor substrate 11, and a region 111C provided at a place at a predetermined depth from the first surface 11S1 in the semiconductor substrate 11. The region 111A is also provided to cover a side surface of a pixel separator 16 described later. The light receiver 13 is pinched between the region 111B and the region 111C in a thickness direction of the semiconductor substrate 11.

Electrons generated in a region between the first surface 11S1 and the region 111C in the semiconductor substrate 11 do not pass through a region of a high electric field, but are collected at the cathode. Therefore, the region between the first surface 11S1 and the region 111C in the semiconductor substrate 11 represents an insensible region for electrons generated in the region between the first surface 11S1 and the region 111C in the semiconductor substrate 11.

The semiconductor substrate 11 is formed with, for each of the pixels P, a trench 11T that has been dug downward from the first surface 11S1. A bottom of the trench 11T is provided with, for example, an n-type semiconductor region in which the concentration of an impurity is controlled to that of the n-type, thereby forming the multiplier 14 for each of the pixels P. That is, the multiplier 14 is disposed at a position at a predetermined depth from the first surface 11S1 of the semiconductor substrate 11. The concentration of an impurity in the multiplier 14 is set higher than the concentration of an impurity in the n-type semiconductor region 112. The multiplier 14 is provided at a position at a depth substantially equal to a depth at which the region 111C is provided in the semiconductor substrate 11. Note that FIG. 1 illustrates a configuration where the multiplier 14 is provided at a location that is slightly shallower than a location at which the region 111C is provided. The region 111C is provided with an opening H at a location facing the multiplier 14. In the opening H, distances between an edge of the opening H and the multiplier 14 are substantially equal to each other regardless of a position on the edge of the opening H. A diameter of the opening H is greater than a width of the multiplier 14.

A contactor 15 buried in the trench 11T is formed inside the trench 11T. The contactor 15 includes, for example, an electrically-conductive material such as metal or polysilicon. That is, an electrically-conductive material such as metal or polysilicon is buried inside the trench 11T. The contactor 15 is in contact with the multiplier 14, and is electrically coupled to the multiplier 14.

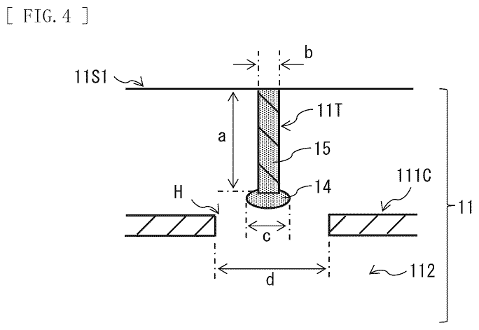

FIG. 4 is an enlarged diagram of the multiplier 14 and its peripheral portion. An aspect ratio (a/b) of the trench 11T is equal to or higher than 2. For example, when a depth a of the trench 11T is 400 nm, a width b of the trench 11T is 200 nm. A width c of the multiplier 14 (for example, a width of a region in which the concentration of an impurity of the n-type is equal to or higher than 1×10¹⁷/cm³) is equal to or wider than 2×b. For example, when the width b of the trench 11T is 200 nm, the width c of the multiplier 14 is 400 nm. The width c of the multiplier 14 changes depending on a tilt angle and thermal diffusion of an impurity when the multiplier 14 is formed through ion implantation. When thermal variation that occurs when the multiplier 14 is formed through ion implantation is taken into account, a maximum value of the width c of the multiplier 14 is approximately 1.5×b. Therefore, when a margin for errors in manufacturing is taken into account, the width c of the multiplier 14 is equal to or narrower than 2×b.

The light receiving element 12 has a multiplication region allowing carriers to undergo avalanche multiplication due to a region of a high electric field, that is, the avalanche multiplication region 12A. The light receiving element 12 is, as described above, an SPAD element that forms an avalanche multiplication region (a depletion layer) when a large positive voltage is applied to the cathode, allowing electrons generated in accordance with entry of one photon to undergo avalanche multiplication.

The light receiver 13 performs photoelectric conversion in which light entered from a side on which the second surface 11S2 of the semiconductor substrate 11 is present is absorbed to generate carriers in accordance with an amount of the light received. The light receiver 13 includes, as described above, the n-type semiconductor region 112 in which the concentration of an impurity is controlled to that of the n-type. The carriers (electrons) generated in the light receiver 13 are transferred to the multiplier 14 due to potential gradient. Note that the light receiver 13 is a specific example corresponding to a “light receiver” in the present disclosure.

The multiplier 14 allows the carriers (electrons in here) generated in the light receiver 13 to undergo avalanche multiplication. The multiplier 14 includes, for example, an n-type semiconductor region (n⁺) that is higher in concentration of an impurity than that in the n-type semiconductor region 112. Note that multiplier 14 is a specific example corresponding to a “multiplier” in the present disclosure.

In the light receiving element 12, the avalanche multiplication region 12A is formed between the multiplier 14 (the n-type semiconductor region (n⁺) described above) and the region 111C of the p-well 111 (specifically, the edge of the opening H). The avalanche multiplication region 12A is a region of a high electric field, which is formed due to a large negative voltage applied to the anode, that is, a depletion layer. In the avalanche multiplication region 12A, electrons (e⁻) that are generated from one photon entering the light receiving element 12 are multiplied.

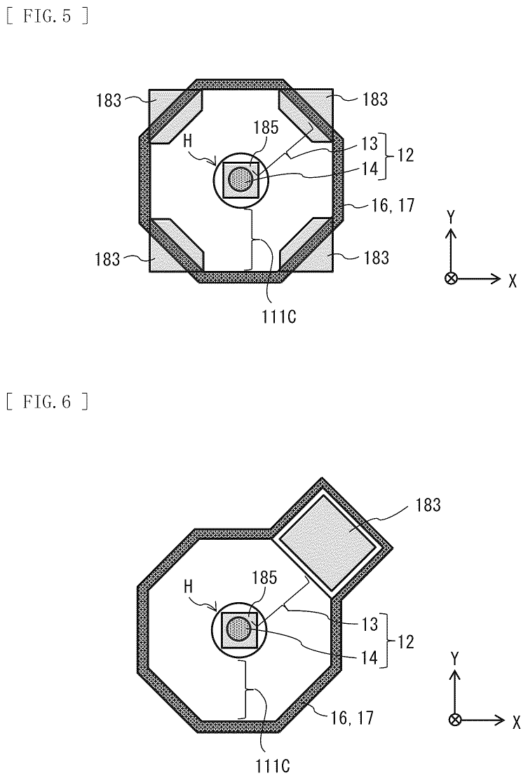

The first surface 11S1 of the semiconductor substrate 11 is provided and in contact with a contact electrode 185. The contact electrode 185 is electrically coupled to the cathode of the light receiving element 12. Specifically, the contact electrode 185 is electrically coupled to the multiplier 14 via the contactor 15. The contact electrode 185 includes, for example, a metal material. Each of the pixels P is provided with, for example, as illustrated in FIG. 5, one contact electrode 185. The one contact electrode 185 is provided, for example, at a center of the pixel P.

The semiconductor substrate 11 is further provided with the pixel separator 16 extending from the first surface 11S1 to the second surface 11S2. The pixel separator 16 is provided to pass through the region 111C in the thickness direction of the semiconductor substrate 11. The pixel separator 16 electrically separates each two of the pixels P, which are adjacent to each other. In a plan view, for example, the pixel separators 16 are provided in a grid in the pixel array 100A to each surround each of the plurality of pixels P. The pixel separator 16 extends from a position near the second surface 11S2 of the semiconductor substrate 11 to the first surface 11S1 of the semiconductor substrate 11. That is, the pixel separator 16 substantially passes through the semiconductor substrate 11.

The pixel separator 16 includes, for example, an electrical conductor 16A and insulation films 16B and 16C. The electrical conductor 16A extends from a position near the second surface 11S2 of the semiconductor substrate 11 to the first surface 11S1 of the semiconductor substrate 11, and includes, for example, a metal material. The insulation films 16B and 16C are lamination films covering a side surface of the electrical conductor 16A, and each include, for example, a film of silicone oxide (SiOₓ).

The first surface 11S1 of the semiconductor substrate 11 is provided and in contact with a contact electrode 183. The contact electrode 183 is electrically coupled to the anode of the light receiving element 12. Specifically, the contact electrode 183 is electrically coupled to the light receiver 13 via the regions 111A and 111C of the p-well 111, a contactor 17, and the electrical conductor 16A. That is, the electrical conductor 16A is electrically coupled to the light receiver 13 via the contactor 17 and the regions 111A and 111C of the p-well 111.

The contactor 17 is formed inside a passivation film 31 described later, and is formed at a location facing the pixel separator 16. The contactor 17 includes, for example, a metal material, and functions as a light shield that prevents crosstalk from occurring between two of the pixels P, which are adjacent to each other. The contact electrode 183 includes, for example, a metal material. FIG. 1 illustrates a structure provided with a plurality of the contact electrodes 183 for each of the pixels P. Each of the pixels P is provided with four contact electrodes 183, as illustrated in FIG. 5, for example. The four contact electrodes 183 are respectively provided at four corners of each of the pixels P, for example. Note that, as illustrated in FIG. 6, each of the pixels P may be provided with one contact electrode 183.

The lamination wiring layer 18 is laminated on the first surface 11S1 opposite to the second surface 11S2 serving as a light-entering surface of the semiconductor substrate 11. In the lamination wiring layer 18, a wiring layer 181 including one wire or a plurality of wires is buried in an interlayer insulation layer 182. The wiring layer 181 serves as, for example, a path for supplying a voltage to be applied to the semiconductor substrate 11 and the light receiving element 12, and for taking carriers generated in the light receiving element 12. A portion of the wire in the wiring layer 181 is electrically coupled to the contact electrode 183 via a via V1. Near a surface, on a side opposite to a side on which the semiconductor substrate 11 is present, of the interlayer insulation layer 182 (a surface 18S1 of the lamination wiring layer 18), a plurality of pad electrodes 184 is buried. The plurality of pad electrodes 184 is each electrically coupled to a portion of the wire of the wiring layer 181 via a via V2.

The wiring layer 181 includes, for example, aluminum (Al), copper (Cu), or tungsten (W). The interlayer insulation layer 182 includes, for example, a single-layer film of one of or a lamination film of two or more of silicon oxide (SiOₓ), TEOS, silicon nitride (SiNₓ), and silicon oxynitride (SiOₓN_{y}). The contact electrode 183 is exposed to the surface 18S1, which serves as a bonding surface with the logic substrate 20, of the lamination wiring layer 18. The contact electrode 183 is, for example, used for coupling to the logic substrate 20. The contact electrode 183 includes, for example, copper (Cu).

The interlayer insulation layer 182 is further provided with the resistance element 51. The resistance element 51 is electrically coupled to the contact electrode 185, and is, for example, a resistive body including a polycristal semiconductor material, such as polysilicon (Poly-Si), including an n-type impurity element. The resistance element 51 includes, for example, a main body 52 extending in parallel to the first surface 11S1, that is, extending along an X-Y plane, and a picker 53 coupling the main body 52 and the contact electrode 185 to each other.

In the example structure illustrated in FIG. 1, the main body 52 and the wiring layer 181 are formed in an identical layer. However, the main body 52 of the resistance element 51 and the wiring layer 181 may be provided in layers different from each other. Another via V2 is provided on an upper surface of the main body 52. That is, the resistance element 51 is electrically coupled to the pad electrode 184 via the via V2. However, for example, another wiring layer such as the wiring layer 181 may be further provided between the main body 52 and the via V2.

The logic substrate 20 includes, for example, a semiconductor substrate 21, which includes a silicon substrate, and a lamination wiring layer 22. The logic substrate 20 includes, for example, the bias voltage applicator 110 described above, a reading circuit that outputs a pixel signal based on an electric charge outputted from each of the unit pixels P in the pixel array 100A, and a logic circuit including a vertical driving circuit, a horizontal driving circuit, and an output circuit, for example. Note that the logic circuit may include a column signal processing circuit.

In the lamination wiring layer 22, for example, a gate wire 221 for a transistor forming the reading circuit and wiring layers 222, 223, 224, and 225 each including one wire or a plurality of wires are laminated in order from a side on which the semiconductor substrate 21 is present. An interlayer insulation layer 226 is provided in a gap between the gate wire 221 for the transistor and the wiring layers 222, 223, 224, and 225 each including one wire or a plurality of wires. On a surface 22S1 of the lamination wiring layer 22, which is a surface on a side opposite to the side on which the semiconductor substrate 21 is present, in the interlayer insulation layer 226, a plurality of pad electrodes 227 is buried. Each of the plurality of pad electrodes 227 is electrically coupled to a portion of the wire in the wiring layer 225 via a via V3.

An interlayer insulation layer 117 includes, similar to the interlayer insulation layer 182, for example, a single-layer film of one of silicon oxide (SiOₓ), TEOS, silicon nitride (SiNₓ), and silicon oxynitride (SiOₓN_{y}) or a lamination film including two or more of the single-layer films.

The gate wire 221 and the wiring layers 222, 223, 224, and 225 include, similar to the wiring layer 181, for example, aluminum (Al), copper (Cu), or tungsten (W). The pad electrode 227 is exposed to the surface 22S1 of the lamination wiring layer 22, which serves as a bonding surface to the sensor substrate 10, and is, for example, coupled to the contact electrode 183 in the sensor substrate 10. The pad electrode 227 includes, similar to the contact electrode 183, for example, copper (Cu).

In the light detection apparatus 1, for example, Cu—Cu bonding is achieved between the contact electrode 183 and the pad electrode 227. Thereby, the cathode of the light receiving element 12 is electrically coupled to a quenching resistance element 120 provided on a side on which the logic substrate 20 is provided. The anode of the light receiving element 12 is electrically coupled to the bias voltage applicator 110. To the light-entering surface, that is, the second surface 11S2, of the semiconductor substrate 11, for example, a micro-lens 33 is provided for each of the unit pixels P via the passivation film 31 and a color filter 32. The color filter 32 is necessary for an imaging purpose, but is not necessary for a ToF purpose. Therefore, the color filter 32 is omitted for the ToF purpose. The micro-lens 33 collects light entered from above into the light receiving element 12, and includes, for example, silicon oxide (SiOₓ).

### Manufacturing Method

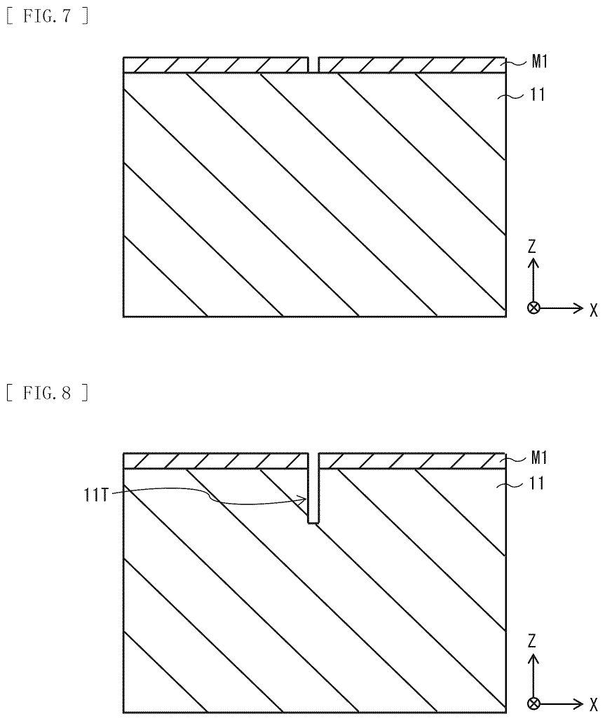

Next, a manufacturing method for the light detection apparatus 1 will now be described herein. FIGS. 7 to 18 schematically illustrate an example of the manufacturing method for the light detection apparatus 1.

An oxide film M1 is first formed on the surface (the first surface 11S1) of the semiconductor substrate 11 (FIG. 7). The oxide film M1 includes, for example, a single-layer film of one of or a lamination film of two or more of silicon oxide (SiOₓ), TEOS, silicon nitride (SiNₓ), and silicon oxynitride (SiOₓN_{y}). A thickness of the oxide film M1 is, for example, 400 nm. Next, an opening is formed at a predetermined location on the oxide film M1 (FIG. 7). A diameter of the opening is, for example, 200 nm.

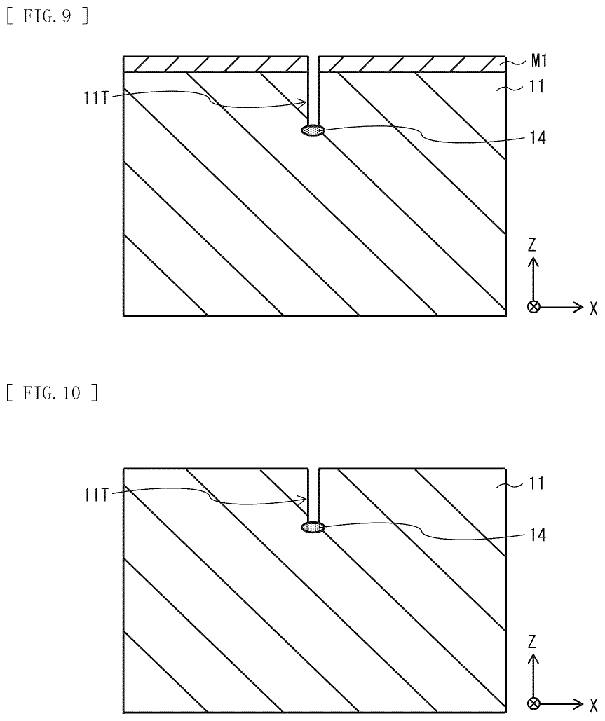

Next, the oxide film M1 is used as a mask to perform dry etching. Thereby, in the semiconductor substrate 11, the trench 11T is formed immediately below the opening on the oxide film M1 (FIG. 8). A depth of the trench 11T is, for example, 400 nm. That is, an aspect ratio of the trench 11T is 2. Then, the oxide film M1 is used as a mask to perform ion implantation. At this time, for example, phosphorus (P) is used as implantation ions. Implantation energy is set to 280 keV. Thereby, it is possible to perform ion implantation with respect to a bottom surface of the trench 11T, making it possible to form, in the semiconductor substrate 11, an n-type impurity region (the multiplier 14) immediately below and only near the trench 11T (FIG. 9). After that, the oxide film M1 is removed (FIG. 10).

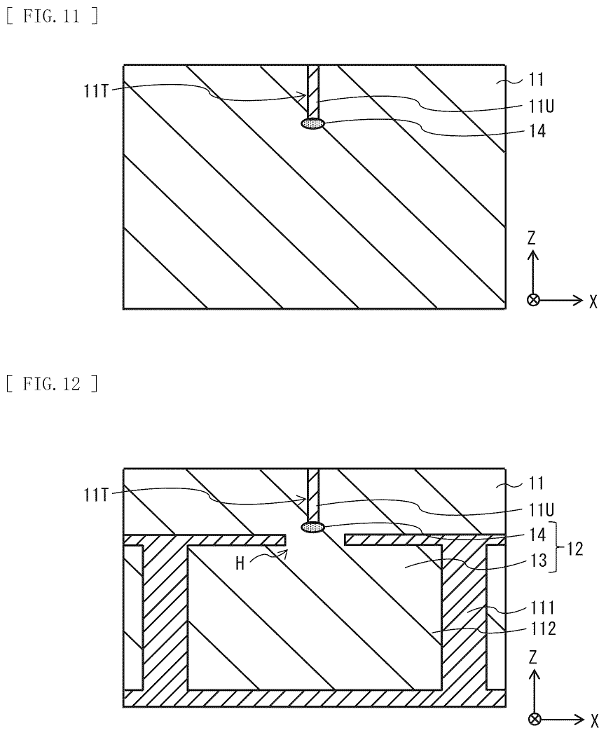

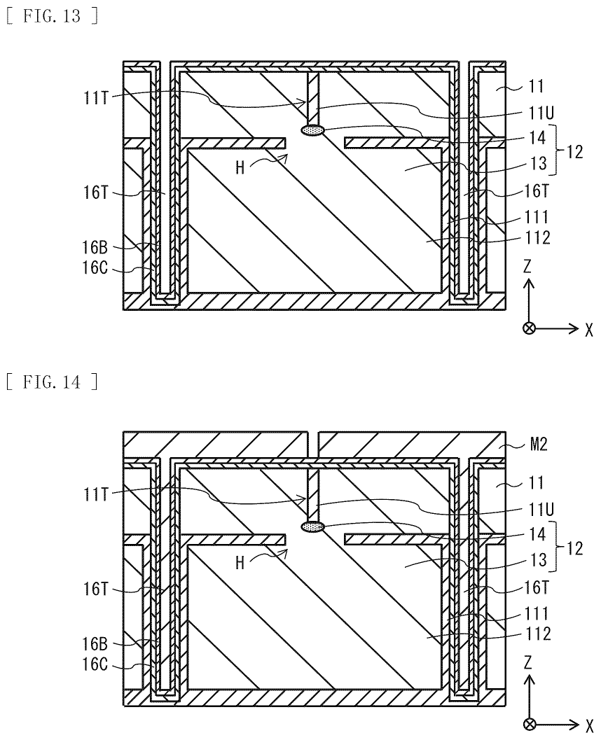

Next, an oxide 11U is buried in the trench 11T (FIG. 11). The p-well 111 and the n-type semiconductor region 112 are formed in the semiconductor substrate 11 (FIG. 12). For example, an ion implantation method is used to form the p-well 111 and the n-type semiconductor region 112. Next, trenches 16T are formed into a grid in the semiconductor substrate 11, for example. The insulation films 16B and 16C are laminated in this order on a whole surface including a side wall and a bottom surface of each of the trenches 16T (FIG. 13).

Next, an oxide film M2 is formed on a surface of the insulation film 16C. The oxide film M2 is, for example, a single-layer film of one of or a lamination film of two or more of silicon oxide (SiOₓ), TEOS, silicon nitride (SiNₓ), and silicon oxynitride (SiOₓN_{y}). A thickness of the oxide film M2 is, for example, 400 nm. Next, an opening is formed at a predetermined location on the oxide film M2 (FIG. 14). A diameter of the opening is, for example, 200 nm.

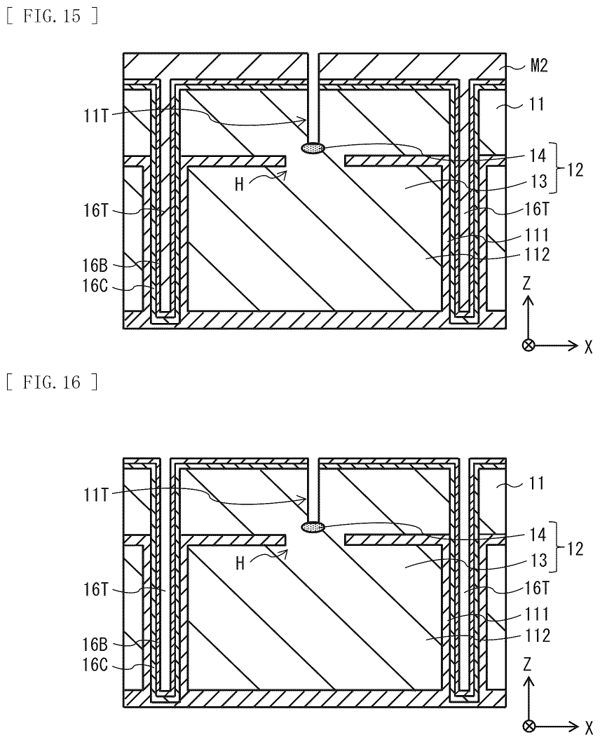

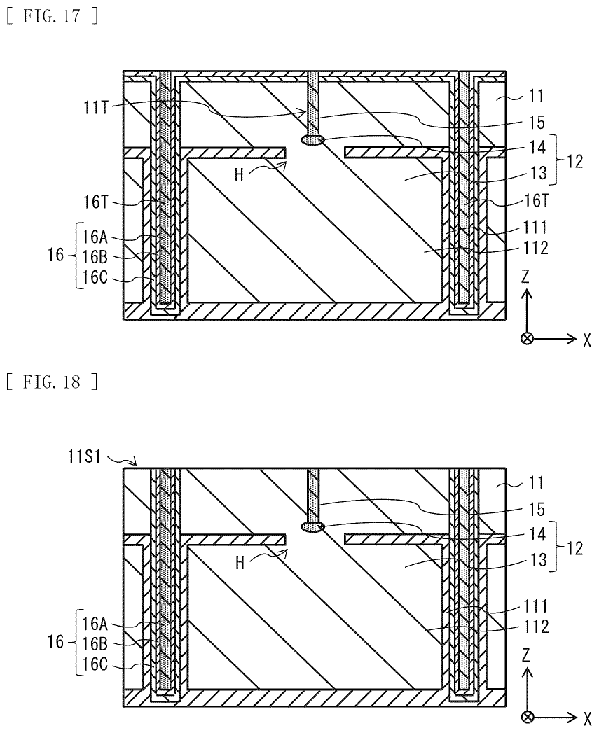

Next, the oxide film M2 is used as a mask to perform dry etching. Thereby, on the insulation films 16B and 16C, an opening is formed immediately below the opening on the oxide film M2, and the oxide 11U inside the trench 11T is removed (FIG. 15). After that, the oxide film M2 is removed (FIG. 16). Next, metal is buried in the trenches 11T and 16T. Thereby, the contactor 15 is formed inside the trench 11T. The electrical conductor 16A is formed inside the trench 16T (FIG. 17). Next, the insulation films 16B and 16C on the first surface 11S1 of the semiconductor substrate 11 are removed (FIG. 18). As described above, the light detection apparatus 1 is manufactured.

Note that an order of forming the light receiver 13 and the multiplier 14 is not particularly limited. Therefore, the multiplier 14 may be formed after the light receiver 13 is formed. The light receiver 13 may otherwise be formed after the multiplier 14 is formed.

### Effects

Next, effects of the light detection apparatus 1 will now be described herein.

In the present embodiment, the multiplier 14 is provided to the bottom surface of the trench 11T. Thereby, it is possible to extend a distance between the multiplier 14 and the pixel separator 16, compared with an ordinary structure where the multiplier is provided to the first surface 11S1 of the semiconductor substrate 11. As a result, in the semiconductor substrate 11, it is possible to lower an electric field in a portion between the multiplier 14 and the pixel separator 16, making it possible to suppress a DCR. Furthermore, even when a distance between the multiplier 14 and the pixel separator 16 is shortened due to a finer configuration, it is possible to mitigate generation of a high electric field, making it possible to suppress a DCR.

In the present embodiment, the contact electrode 183 serving as the anode electrode of the light receiving element 12 is electrically coupled to the light receiver 13 via the electrical conductor 16A forming the pixel separator 16. Thereby, it is possible to suppress generation of a high electric field near the side surface of the pixel separator 16, compared with an ordinary structure where the anode electrode is electrically coupled to the light receiver 13 via a p-well formed around a pixel separator. As a result, it is possible to suppress a DCR. Furthermore, even when a distance between the multiplier 14 and the pixel separator 16 is shortened due to a finer configuration, it is possible to mitigate generation of a high electric field, making it possible to suppress a DCR.

In the present embodiment, the p-well 111 (the region 111C) is formed at a place at a predetermined depth from the first surface 11S1 in the semiconductor substrate 11. Thereby, electrons generated in a region between the first surface 11S1 and the region 111C do not pass through a region of a high electric field, but are collected at the cathode. Therefore, the region between the first surface 11S1 and the region 111C in the semiconductor substrate 11 represents an insensible region for electrons generated in the region between the first surface 11S1 and the region 111C in the semiconductor substrate 11. In the present embodiment, as described above, the region between the first surface 11S1 and the region 111C in the semiconductor substrate 11 represents an insensible region. As a result, it is possible to suppress a DCR. Furthermore, even when a distance between the multiplier 14 and the pixel separator 16 is shortened due to a finer configuration, presence of an insensible region makes it possible to suppress a DCR.

In the present embodiment, performing ion implantation with respect to the bottom surface of the trench 11T allows an n-type impurity region (the multiplier 14) to be formed immediately below and only near the trench 11T in the semiconductor substrate 11. Thereby, compared with a case when ion implantation is performed with respect to the first surface 11S1 of the semiconductor substrate 11, it is possible to form a small multiplier 14 at a deep location in the semiconductor substrate 11. As a result, in the semiconductor substrate 11, it is possible to lower an electric field in a portion between the multiplier 14 and the pixel separator 16, making it possible to suppress a DCR. Furthermore, even when a distance between the multiplier 14 and the pixel separator 16 is shortened due to a finer configuration, it is possible to mitigate generation of a high electric field, making it possible to suppress a DCR.

Furthermore, in the present embodiment, it is possible to form the multiplier 14 with low energy, making it possible to reduce damage due to ion implantation. Furthermore, it is possible to set distribution of impurity density in the multiplier 14 to steep distribution, making it possible to lower a voltage necessary for deriving multiplication.

In the present embodiment, the oxide film M1 is shared as a mask for forming the trench 11T and a mask for forming the multiplier 14. Thereby, it is possible to form the multiplier 14 at and only near the bottom surface of the trench 11T. As a result, compared with a case when ion implantation is performed with respect to the first surface 11S1 of the semiconductor substrate 11, it is possible to form a small multiplier 14 at a deep location in the semiconductor substrate 11. Therefore, in the semiconductor substrate 11, it is possible to lower an electric field in a portion between the multiplier 14 and the pixel separator 16, making it possible to suppress a DCR. Furthermore, even when a distance between the multiplier 14 and the pixel separator 16 is shortened due to a finer configuration, it is possible to mitigate generation of a high electric field, making it possible to suppress a DCR.

### 3. Modification Examples

Next, modification examples of the light detection apparatus 1 according to the embodiment described above will now be described herein.

### Modification Example A

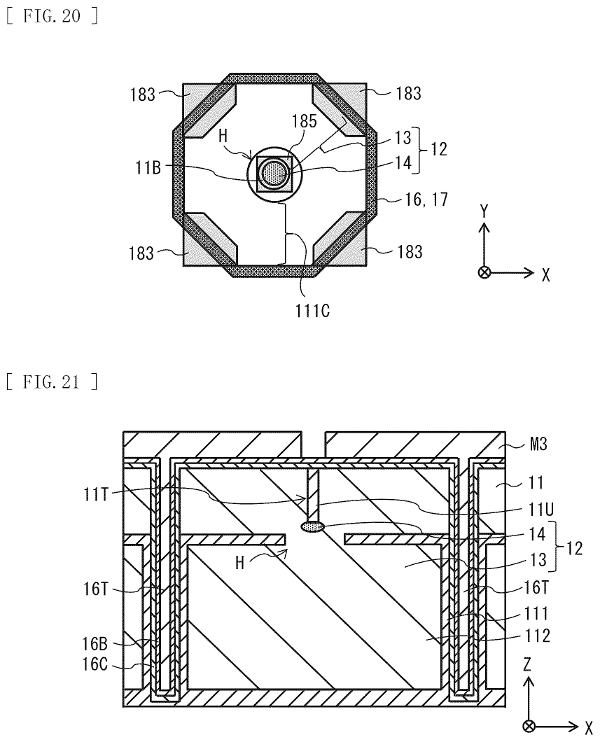

In the semiconductor substrate 11 according to the embodiment described above, an oxide film 11B that covers the side surface of the trench 11T (the contactor 15) may be provided, as illustrated in FIGS. 19 and 20, for example. FIG. 19 schematically illustrates an example of a cross-sectional configuration of the light detection apparatus 1 according to the present modification example. FIG. 20 illustrates an example of a horizontal cross-sectional configuration at a location including the oxide film 11B in the semiconductor substrate 11. The oxide film 11B includes, for example, a single-layer film of one of or a lamination film of two or more of silicon oxide (SiOₓ), TEOS, silicon nitride (SiNₓ), and silicon oxynitride (SiOₓN_{y}).

As described above, providing the oxide film 11B covering the side surface of the trench 11T (the contactor 15) allows an electric potential at the cathode to be transmitted to a portion between the oxide film 11B and the pixel separator 16 in the semiconductor substrate 11 via the oxide film 11B. As a result, in the semiconductor substrate 11, it is possible to lower an electric field in the portion between the oxide film 11B and the pixel separator 16, making it possible to suppress a DCR.

### Modification Example B

In the embodiment described above and Modification Example A, the contactor 15 may be formed not only inside the trench 11T, but also outside the trench 11T. For the contactor 15, for example, a vertical cross section of the contactor 15 may be a T-letter shape.

Next, a manufacturing method for the light detection apparatus 1 according to the present modification example will now be described herein. FIGS. 21 to 25 schematically illustrate an example of the manufacturing method for the light detection apparatus 1 according to the present modification example.

Similar to the embodiment described above, steps described with reference to FIGS. 7 to 13 are first performed. Next, a resist layer M3 is formed on the surface of the insulation film 16C. A thickness of the resist layer M3 corresponds to a thickness for substantially withstanding dry etching to be performed subsequently, and is, for example, 2000 nm. Next, an opening is formed at a predetermined location on the resist layer M3 (FIG. 21). A diameter of the opening is, for example, 500 nm. A reason of why the opening on the resist layer M3 is greater than the opening on the oxide film M2 is to take into account a margin for a positional error that may occur when the opening is formed on the resist layer M3.

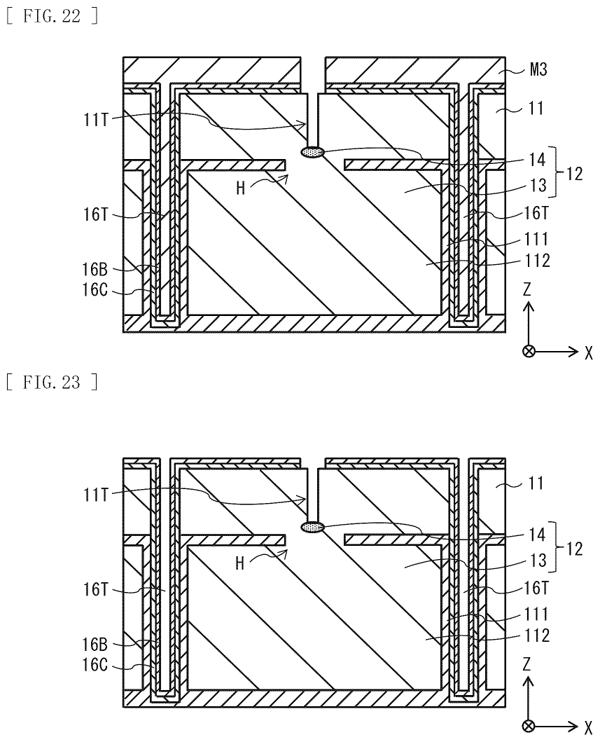

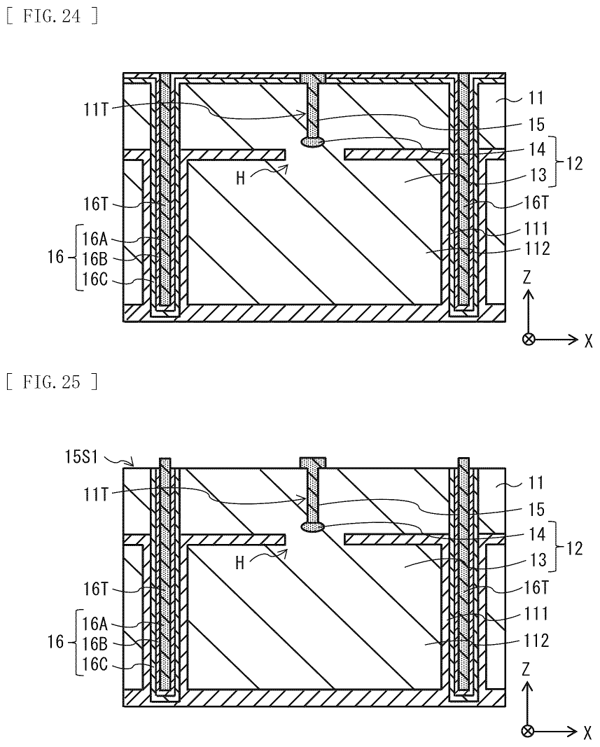

Next, the resist layer M3 is used as a mask to perform dry etching. Thereby, on the insulation films 16B and 16C, an opening is formed immediately below the opening on the resist layer M3, and the oxide 11U inside the trench 11T is removed (FIG. 22). After that, the oxide film M2 is removed (FIG. 23). Next, metal is buried in the trenches 11T and 16T. Thereby, the contactor 15 is formed inside the trench 11T. The electrical conductor 16A is formed inside the trench 16T (FIG. 24). Next, the insulation films 16B and 16C on the first surface 11S1 of the semiconductor substrate 11 are removed (FIG. 25). As described above, the light detection apparatus 1 according to the present modification example is manufactured.

In the present modification example, a wide opening is formed on the resist layer M3. Thereby, it is possible to securely remove the insulation films 16B and 16C and the oxide 11U immediately below the opening on the resist layer M3. As a result, it is possible to prevent electrons and holes from being generated from an interface level at an interface between the remained oxide film and the silicon, making it possible to suppress a DCR.

### Modification Example C

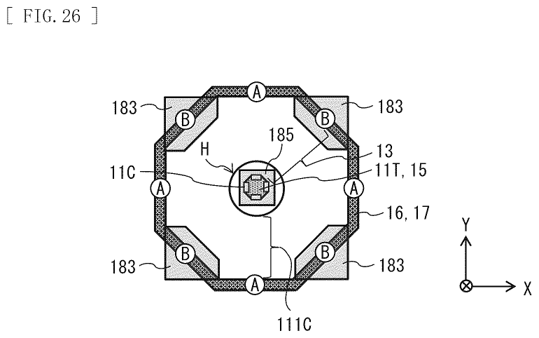

In Modification Example A described above, an oxide film 11C that partially covers the side surface of the trench 11T (the contactor 15) may be provided, instead of the oxide film 11B, as illustrated in FIG. 26, for example. The oxide film 11C is, for example, provided at locations respectively facing locations (points A), excluding the four corners in each of the pixels P, and is not provided at locations facing the four corners (points B) in each of the pixels P. That is, on the side surface of the trench 11T (the contactor 15), the locations facing the points A are covered with the oxide film 11C, and, on the side surface of the trench 11T (the contactor 15), the locations facing the points B are not covered with the oxide film 11C, but the metal is exposed.

Note herein that a distance between the side surface of the trench 11T (the contactor 15) and each of the points A is shorter than a distance between the side surface of the trench 11T (the contactor 15) and each of the points B. Therefore, a depletion layer easily becomes narrow between the side surface of the trench 11T (the contactor 15) and each of the points A, easily generating a high electric field. However, in the present modification example, the locations respectively facing the points A are covered with the oxide film 11C on the side surface of the trench 11T (the contactor 15). Thereby, it is possible to mitigate generation of an electric field between the side surface of the trench 11T (the contactor 15) and each of the points A. On the other hand, on the side surface of the trench 11T (the contactor 15), the metal is exposed at the locations that are not covered with the oxide film 11C, making it possible to collect electrons generated around the anode at the locations that are not covered with the oxide film 11C, on the side surface of the trench 11T (the contactor 15).

As described above, in the present modification example, the oxide film 11C is selectively provided only at the locations at which a high electric field is easily generated (that is, the locations each at a relatively short distance between the side surface of the trench 11T (the contactor 15) and the pixel separator 16). Thereby, it is possible to prevent electrons from being uncollected, making it possible to suppress a DCR.

### Modification Example D

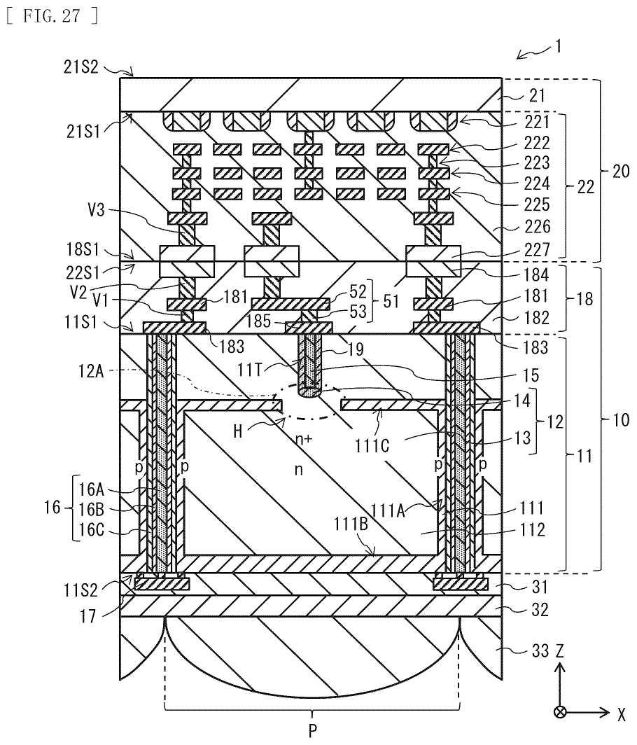

In the embodiment described above, an n-type neutral region 19 that covers the side surface of the trench 11T (the contactor 15) may be provided, as illustrated in FIG. 27, for example. The concentration of an impurity in the n-type neutral region 19 is set higher than the concentration of an impurity in the n-type semiconductor region 112. It is possible to form the n-type neutral region 19 by, for example, applying a tilt angle and performing ion implantation, or performing solid-phase diffusion or plasma doping.

As described above, providing the n-type neutral region 19 to the side surface of the trench 11T (the contactor 15) makes it possible to assist pinning effect that is achieved due to the contactor 15 (metal).

### Modification Example E

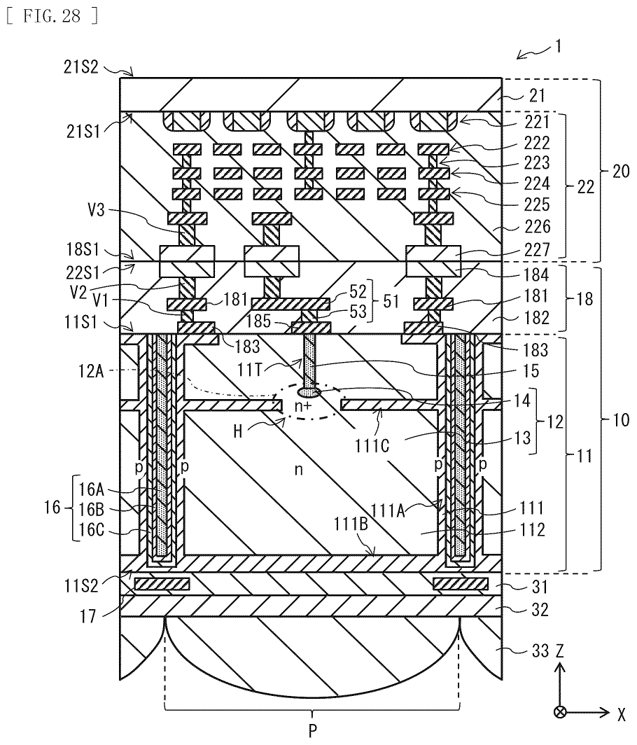

In the embodiment described above, the contact electrode 183 may be in direct contact with the p-well 111 without the electrical conductor 16A interposed, as illustrated in FIG. 28, for example. In the present modification example, the p-well 111 is formed to be in contact with the side surface of the pixel separator 16, and extends from the first surface 11S1 to the second surface 11S2 in the semiconductor substrate 11. Even in such a case as described above, the multiplier 14 is formed sufficiently away from the pixel separator 16, making it possible to mitigate an increase in electric field in a portion between the trench 11T (the contactor 15) and the pixel separator 16 in the semiconductor substrate 11. As a result, it is possible to suppress a DCR.

### Modification Example F

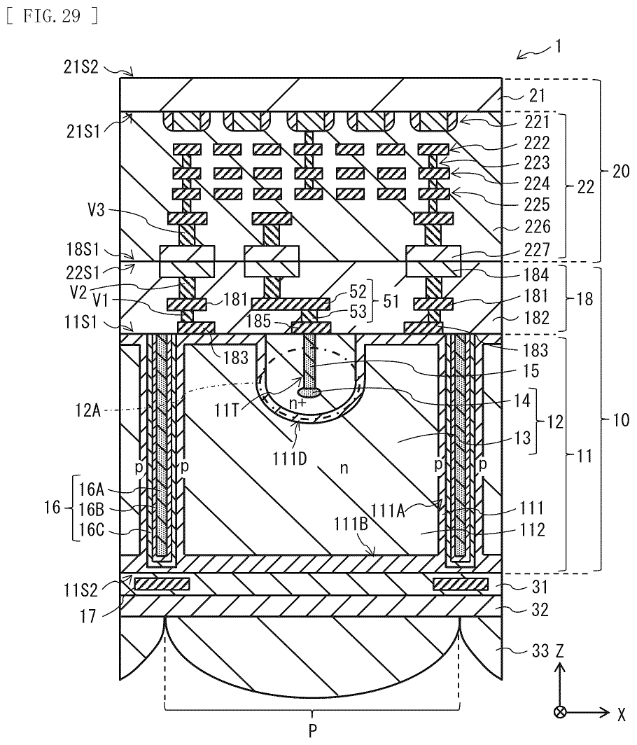

In Modification Example E described above, the p-well 111 may include a region 111D that covers the trench 11T (the contactor 15) and the multiplier 14 at a location at a predetermined distance, instead of the region 111C, as illustrated in FIG. 29, for example. The region 111D is a p-type semiconductor region having a dome shape covering the multiplier 14, and is in contact with the contact electrode 183 via the first surface 11S1. In such a case as described above, the avalanche multiplication region 12A is formed near the first surface 11S1 of the semiconductor substrate 11, making it possible to secure a wide sensing region.

### 4. Application Example

FIG. 30 illustrates an example of an outline configuration of the distance image apparatus 1000 representing an electronic apparatus including the light detection apparatus 1 according to any one of the embodiment described above and its modification examples.

The distance image apparatus 1000 includes, for example, a light source apparatus 1100, an optical system 1200, the light detection apparatus 1, an image processing circuit 1300, a monitor 1400, and a memory 1500.

The distance image apparatus 1000 receives light (modulated light or pulse light) that is emitted from the light source apparatus 1100 toward the light irradiation target 2000 and that is reflected on a surface of the light irradiation target 2000, making it possible to acquire a distance image in accordance with a distance to the light irradiation target 2000.

The optical system 1200 includes one lens or a plurality of lenses, leads image light (incident light) from the light irradiation target 2000 toward the light detection apparatus 1, and allows a light receiving surface (a sensor) of the light detection apparatus 1 to form an image.

The image processing circuit 1300 performs image processing for forming a distance image based on a distance signal supplied from the light detection apparatus 1, and allows a distance image (image data) acquired through the image processing to be supplied to and displayed on the monitor 1400 and to be supplied to and stored (recorded) in the memory 1500.

In the distance image apparatus 1000 configured as described above, applying the light detection apparatus described above (for example, the light detection apparatus 1) makes it possible to calculate a distance to the light irradiation target 2000 based on highly stable light receiving signals supplied from the unit pixels P only, and to generate a highly precise distance image. That is, the distance image apparatus 1000 makes it possible to acquire a highly accurate distance image.

### 5. Practical Example

### Practical Example to Movable Body

It is possible to apply the technique according to the present disclosure to various products. For example, the technique according to the present disclosure may be achieved as a device mounted in any types of movable bodies including vehicles, electric vehicles, hybrid electric vehicles, motorcycles, bicycles, personal mobilities, airplanes, drones, ships and vessels, robots, construction machines, and agricultural machines (tractors).

FIG. 31 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 31, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 31, an audio speaker 12061, a display section 12062, and an instrument panel 12063 are illustrated as the output device. The display section 12062 may, for example, include at least one of an on-board display and a head-up display.

FIG. 32 is a diagram depicting an example of the installation position of the imaging section 12031.

In FIG. 32, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 32 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which it is possible to apply the technique of the present disclosure has been described. The technique of the present disclosure may be applied to the imaging section 12031, among the components described above. Applying the technique according to the present disclosure to the imaging section 12031 makes it possible to perform further accurate cooperation control.

Although the present disclosure has been described with reference to the embodiment and the modification examples, the present disclosure is not limited to the above-described embodiment and the like, and various modifications are possible.

In the embodiment described above and its modification examples, the polarities in the semiconductor regions forming the light detection apparatus 1 may be inversed. Furthermore, in the embodiment described above and its modification examples, the light detection apparatus 1 may use holes as a signal electric charge.

Furthermore, in the light detection apparatus 1, in the embodiment described above and its modification examples, there is no limitation in each electric potential, as long as it is possible to achieve a state where avalanche multiplication occurs when reverse bias is applied between the anode and the cathode.

Furthermore, in the embodiment described above and its modification examples, it has been described an example of using silicon as the semiconductor substrate 11. However, it is possible to use, for example, semiconductor including germanium (Ge) or chemical compound semiconductor including silicon (Si) and germanium (Ge) (for example, silicon germanium (SiGe)) as the semiconductor substrate 11.

It should be appreciated that the effects described herein are mere examples. The effects of the present disclosure are not limited to the effects described in the present specification. The present disclosure may have effects other than the effects described herein.

Furthermore, for example, the present disclosure may have configurations described below.
(1)

A light detection apparatus includes:
a semiconductor substrate having a first surface and a second surface facing each other, and having a pixel array in which a plurality of pixels is disposed into an array shape in an in-plane direction;
a light receiver provided inside the semiconductor substrate for each of the pixels, the light receiver generating, through photoelectric conversion, carriers in accordance with an amount of light received;
a trench provided, for each of the pixels, to the first surface of the semiconductor substrate;
a multiplier that is a first electrically-conductive type, the multiplier being provided to a bottom surface of the trench, the multiplier allowing the carriers generated in the light receiver to undergo avalanche multiplication; and
a contactor including an electrically-conductive material buried in the trench, the contactor being in contact with the multiplier.
(2)

The light detection apparatus described in (1), in which an aspect ratio of the trench is equal to or higher than 2.
(3)

The light detection apparatus described in (1) or (2)
further includes a pixel separator provided inside the semiconductor substrate, the pixel separator separating each of the plurality of pixels,
in which
the pixel separator includes an electrical conductor having a side surface covered with an insulation film, and
the electrical conductor is electrically coupled to the light receiver.
(4)

The light detection apparatus described in (3)
further includes:
a first impurity semiconductor region that is a second electrically-conductive type that differs from the first electrically-conductive type, the first impurity semiconductor region being provided, in the semiconductor substrate, at a place at a predetermined depth from the first surface; and
a second impurity semiconductor region that is the second electrically-conductive type, the second impurity semiconductor region being provided, in the semiconductor substrate, to cover a side surface of the light receiver,
in which the electrical conductor is electrically coupled to the light receiver via the first impurity semiconductor region and the second impurity semiconductor region.
(5)

The light detection apparatus described in (3) further includes an oxide film provided inside the semiconductor substrate, the oxide film being provided to cover a side surface of the trench.
(6)

The light detection apparatus described in any one of (1) to (5), in which the contactor has a T-letter shape in vertical cross section, and is formed to be not only buried in the trench, but also provided to outside of the trench.
(7)

The light detection apparatus described in (3) further includes an oxide film selectively provided inside the semiconductor substrate and on a side surface of the trench only at a location at a relatively short distance between the side surface of the trench and the pixel separator.
(8)

The light detection apparatus described in (3) further includes an impurity region that is the first electrically-conductive type, the impurity region being provided inside the semiconductor substrate, the impurity region being provided to cover a side surface of the trench.
(9)

The light detection apparatus described in (1)
further includes:
a pixel separator provided inside the semiconductor substrate, the pixel separator separating each of the plurality of pixels;
a first impurity semiconductor region that is a second electrically-conductive type that differs from the first electrically-conductive type, the first impurity semiconductor region being provided, in the semiconductor substrate, at a place at a predetermined depth from the first surface;
a third impurity semiconductor region that is the second electrically-conductive type, the third impurity semiconductor region being provided, in the semiconductor substrate, to cover a side surface of the pixel separator, and
a contact electrode provided to the first surface, the contact electrode being electrically coupled to the light receiver via the first impurity semiconductor region and the third impurity semiconductor region.
(10)

The light detection apparatus described in (1) further includes a fourth impurity semiconductor region that is the second electrically-conductive type, the fourth impurity semiconductor region being provided inside the semiconductor substrate, the fourth impurity semiconductor region having a dome shape covering the multiplier.
(11)

A manufacturing method for a light detection apparatus, the method including:
forming, inside a semiconductor substrate having a first surface and a second surface, for each of pixels, a light receiver generating, through photoelectric conversion, carriers in accordance with an amount of light received;
forming, on the first surface of the semiconductor substrate, an oxide film having a first opening for each of the pixels;
using the oxide film as a mask and performing dry etching to form a trench immediately below the opening on the semiconductor substrate;
using the oxide film as a mask and performing ion implantation to form a multiplier that is a first electrically-conductive type immediately below the trench in the semiconductor substrate, the multiplier allowing the carriers generated in the light receiver to undergo avalanche multiplication; and
burying an electrically-conductive material in the trench to form a contactor that is in contact with the multiplier.

In the light detection apparatus according to the embodiment of the present disclosure, the multiplier is provided to the bottom surface of the trench. Thereby, it is possible to extend a distance between the multiplier and the pixel separator, compared with an ordinary structure where the multiplier is provided to the first surface of the semiconductor substrate. As a result, in the semiconductor substrate, it is possible to lower an electric field in a portion between the multiplier and the pixel separator, making it possible to suppress a DCR. Furthermore, even when a distance between the multiplier and the pixel separator is shortened due to a finer configuration, it is possible to mitigate generation of a high electric field, making it possible to suppress a DCR.

With the manufacturing method for the light detection apparatus according to the embodiment of the present disclosure, performing ion implantation with respect to the bottom surface of the trench allows the multiplier to be formed immediately below the trench in the semiconductor substrate. Thereby, compared with a case when ion implantation is performed with respect to the first surface of the semiconductor substrate, it is possible to form a small multiplier at a deep location in the semiconductor substrate. As a result, in the semiconductor substrate, it is possible to lower an electric field in a portion between the multiplier and the pixel separator, making it possible to suppress a DCR. Furthermore, it is possible to form the multiplier with low energy, making it possible to reduce damage due to ion implantation. Furthermore, it is possible to set distribution of impurity density in the multiplier to steep distribution, making it possible to lower a voltage necessary for deriving multiplication. Furthermore, even when a distance between the multiplier and the pixel separator is shortened due to a finer configuration, it is possible to mitigate generation of a high electric field, making it possible to suppress a DCR.

1. A light detection apparatus comprising:
a semiconductor substrate having a first surface and a second surface facing each other, and having a pixel array in which a plurality of pixels is disposed into an array shape in an in-plane direction;
a light receiver provided inside the semiconductor substrate for each of the pixels, the light receiver generating, through photoelectric conversion, carriers in accordance with an amount of light received;
a trench provided, for each of the pixels, to the first surface of the semiconductor substrate;
a multiplier that is a first electrically-conductive type, the multiplier being provided to a bottom surface of the trench, the multiplier allowing the carriers generated in the light receiver to undergo avalanche multiplication; and
a contactor including an electrically-conductive material buried in the trench, the contactor being in contact with the multiplier.

2. The light detection apparatus according to claim 1, wherein an aspect ratio of the trench is equal to or higher than 2.

3. The light detection apparatus according to claim 1,
further comprising a pixel separator provided inside the semiconductor substrate, the pixel separator separating each of the plurality of pixels,
wherein
the pixel separator includes an electrical conductor having a side surface covered with an insulation film, and
the electrical conductor is electrically coupled to the light receiver.

4. The light detection apparatus according to claim 3,
further comprising:
a first impurity semiconductor region that is a second electrically-conductive type that differs from the first electrically-conductive type, the first impurity semiconductor region being provided, in the semiconductor substrate, at a place at a predetermined depth from the first surface; and
a second impurity semiconductor region that is the second electrically-conductive type, the second impurity semiconductor region being provided, in the semiconductor substrate, to cover a side surface of the light receiver,
wherein the electrical conductor is electrically coupled to the light receiver via the first impurity semiconductor region and the second impurity semiconductor region.

5. The light detection apparatus according to claim 3, further comprising an oxide film provided inside the semiconductor substrate, the oxide film being provided to cover a side surface of the trench.

6. The light detection apparatus according to claim 1, wherein the contactor has a T-letter shape in vertical cross section, and is formed to be not only buried in the trench, but also provided to outside of the trench.

7. The light detection apparatus according to claim 3, further comprising an oxide film selectively provided inside the semiconductor substrate and on a side surface of the trench only at a location at a relatively short distance between the side surface of the trench and the pixel separator.

8. The light detection apparatus according to claim 3, further comprising an impurity region that is the first electrically-conductive type, the impurity region being provided inside the semiconductor substrate, the impurity region being provided to cover a side surface of the trench.

9. The light detection apparatus according to claim 1,
further comprising:
a pixel separator provided inside the semiconductor substrate, the pixel separator separating each of the plurality of pixels;
a first impurity semiconductor region that is a second electrically-conductive type that differs from the first electrically-conductive type, the first impurity semiconductor region being provided, in the semiconductor substrate, at a place at a predetermined depth from the first surface;
a third impurity semiconductor region that is the second electrically-conductive type, the third impurity semiconductor region being provided, in the semiconductor substrate, to cover a side surface of the pixel separator, and
a contact electrode provided to the first surface, the contact electrode being electrically coupled to the light receiver via the first impurity semiconductor region and the third impurity semiconductor region.

10. The light detection apparatus according to claim 1, further comprising a fourth impurity semiconductor region that is the second electrically-conductive type, the fourth impurity semiconductor region being provided inside the semiconductor substrate, the fourth impurity semiconductor region having a dome shape covering the multiplier.

11. A manufacturing method for a light detection apparatus, the method comprising:
forming, inside a semiconductor substrate having a first surface and a second surface, for each of pixels, a light receiver generating, through photoelectric conversion, carriers in accordance with an amount of light received;
forming, on the first surface of the semiconductor substrate, an oxide film having a first opening for each of the pixels;
using the oxide film as a mask and performing dry etching to form a trench immediately below the opening on the semiconductor substrate;
using the oxide film as a mask and performing ion implantation to form a multiplier that is a first electrically-conductive type immediately below the trench in the semiconductor substrate, the multiplier allowing the carriers generated in the light receiver to undergo avalanche multiplication; and
burying an electrically-conductive material in the trench to form a contactor that is in contact with the multiplier.
